(19) United States
(12) Patent Application Publication
(10) Pub. No.: US 2003/0234426 A1
(43) Pub. Date: Dec. 25, 2003

(54) Electrostatic discharge protection device

(76) Inventors: Meng-Huang Liu, Hsinchu Hsien (TW); Chun-Hsiang Lai, Taichung City (TW); Shin Su, Taipei Hsien (TW); Tao-Cheng Lu, Kaohsiung City (TW)

Correspondence Address: BIRCH STEWART KOLASCH & BIRCH, PO BOX 747, FALLS CHURCH, VA, 22040-0747, US

(21) Appl. No.: 10/273,890

(22) Filed: Oct. 21, 2002

(30) Foreign Application Priority Data
Jun. 24, 2002 (TW) 091113772

(51) Int. Cl. H01L 23/62

(52) U.S. Cl. 257/355

(57) ABSTRACT

An ESD protection device. The ESD protection device is set between a memory device, a second voltage level and a pad coupled to a first voltage level. The ESD protection device includes a first second type doped region formed on the first type substrate and coupled to the first voltage level, a second second type doped region formed on the first type substrate and coupled to the second voltage level, a third second type doped region formed on the first type substrate, a second type well formed between the first second type doped region and the third second type doped region, and an isolation element formed between the second second type doped region and the third second type doped region.

### BACKGROUND OF THE INVENTION

1. Field of the Invention

The present invention relates generally to an electrostatic discharge (ESD hereinafter) protection device and more particularly to an ESD protection device with high voltage pad. The holding voltage of the ESD protection device is increased by separating the drain and inserting an N well between the separated drains.

2. Description of the Related Art

In memory products, especially for EPROM and Flash memory, high voltage has to be applied to perform special applications such as program/erase. Possible overshoot may occur when the high voltage is applied. Thus, the high voltage pad should be capable of withstanding such an overshoot. On the other hand, this high-voltage pad should also have enough ESD performance to resist high current, fast transient ESD events.

FIG. 1 shows a block diagram of the input terminal of a memory device. Generally, the ESD protection device 12 is set between a pad 10 and a memory device 14.

FIG. 2 shows a sectional view of the conventional ESD protection device. The N-type doped regions 23 and 24 are formed on the P-type substrate 22, wherein the P-type substrate 22 and the N-type doped region 24 are coupled to the ground level, and the N-type doped region 23 is coupled to a pad 20 providing the outside signals.

In addition, the N-type doped region 23, the P-type substrate 22 and N-type doped region 24 construct a bipolar junction transistor (BJT hereinafter) Q0. When the ESD event occurs at the pad 20, a large ESD current turns on the parasitical BJT Q0 of the ESD protection device and flows to the ground through the substrate 22 to prevent ESD damage to the memory device.

FIG. 3 shows the drain current of the conventional ESD protection device against the input voltage. Under ESD events, when the voltage level of the pad is higher than the trigger voltage, the ESD protection device is enabled and immediately goes to snapback mode with a low holding voltage to decrease the voltage level of the pad to prevent ESD damage to the memory device. Thus, the low holding voltage is beneficial to ESD resistivity.

However, under normal high-voltage application, when the voltage overshoot larger than the trigger voltage, the ESD device would be also enabled unexpected and goes to snapback mode with low holding voltage. But when high voltage returned to its stable state, the ESD device might be still in its snapback mode because holding voltage was lower than stable high-voltage state. Thus, the drain current of the BJT increases with the increasing voltage and reaches to I_{HV} as shown in FIG. 3. The large drain current combined with high voltage will damage the ESD protection device due to the high power. Accordingly, the problem occurs when the high level signal of the conventional ESD protection device is higher than the holding voltage. Therefore, the conventional ESD protection device in holding mode outputs large current when receiving high level signals and will be damaged by the large current.

### SUMMARY OF THE INVENTION

The object of the present invention is to provide an ESD protection device having a holding voltage higher than the high level signal received by the pad to avoid the problem mentioned above. In addition, the ESD protection device of the present invention adds another discharge path to increase discharge effect.

To achieve the above-mentioned object, the present invention provides an ESD protection device set between a memory device, a second voltage level and a pad coupled to a first voltage level. The ESD protection device includes the following elements. A first second type doped region is formed on the first type substrate and coupled to the first voltage level. A second second type doped region is formed on the first type substrate and coupled to the second voltage level. A third second type doped region is formed on the first type substrate. A second type well is formed between the first second type doped region and the third second type doped region. An isolation element is formed between the second second type doped region and the third second type doped region.

### BRIEF DESCRIPTION OF THE DRAWINGS

The present invention will become more fully understood from the detailed description given hereinbelow and the accompanying drawings, given by way of illustration only and thus not intended to be limitative of the present invention.

FIG. 1 shows a block diagram of an input terminal of a memory device having an ESD protection device.

FIG. 2 shows a sectional view of a conventional ESD protection device.

FIG. 3 shows the drain current of the conventional ESD protection device against the input voltage.

FIG. 4 shows a sectional view of an ESD protection device according to the embodiment of the present invention.

FIG. 5 shows the drain current of the ESD protection device against the input voltage according to the embodiment of the present invention.

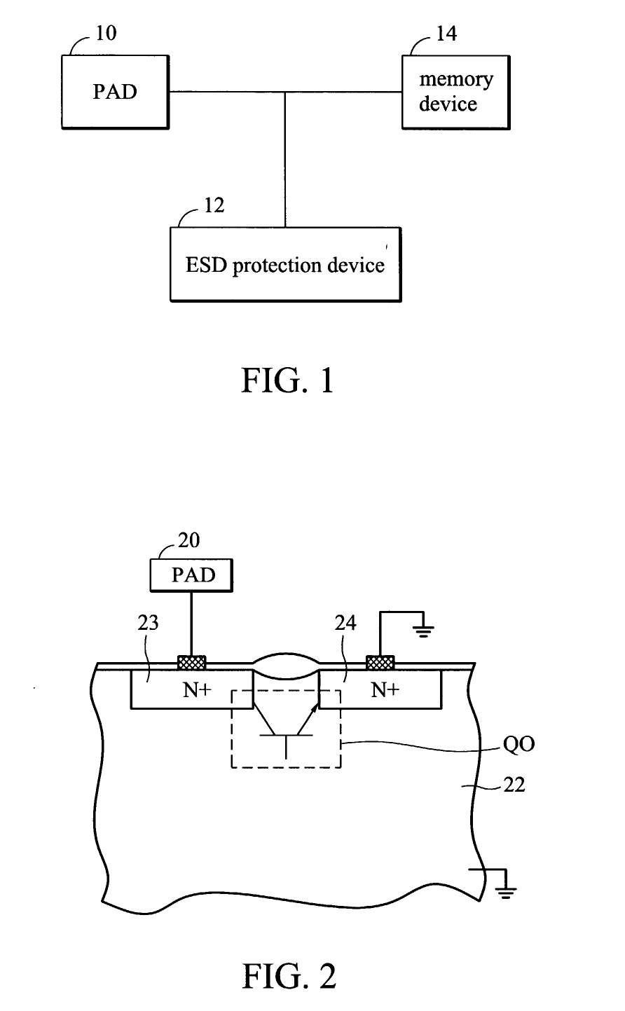

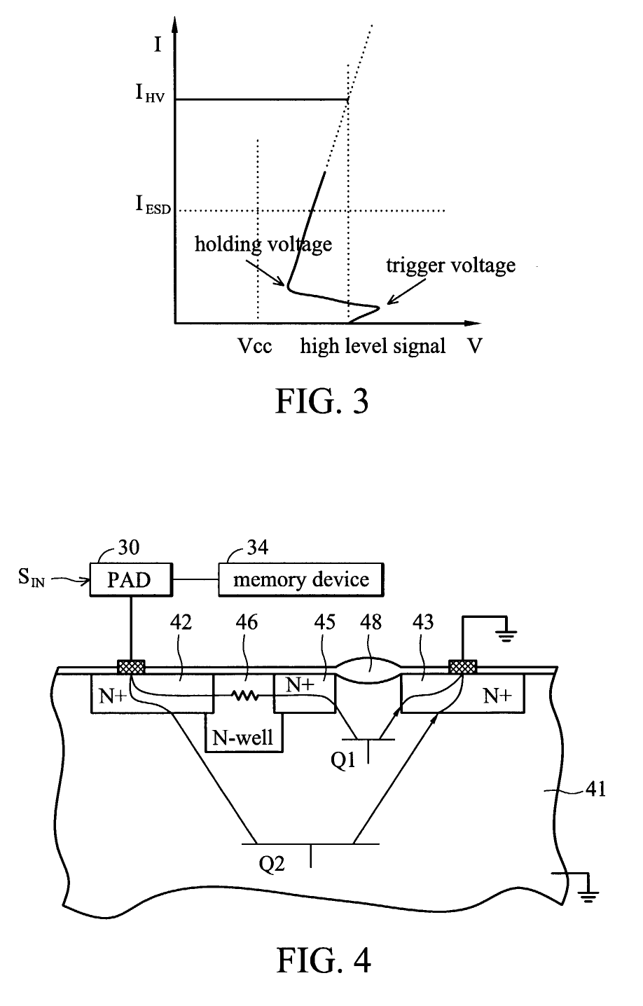

### DETAILED DESCRIPTION OF THE INVENTION

FIG. 4 shows a sectional view of an ESD protection device according to the embodiment of the present invention. The ESD protection device according to the embodiment of the present invention is set between the pad 30 coupled to the input signal S_{IN} and the memory device 34 and the ground level.

The P-type substrate 41 is coupled to the ground level. The first N-type doped region 42 is formed on the P-type substrate 41 and is coupled to the input signal S_{IN} through the pad 30. The second N-type doped region 43 is formed on the P-type substrate 41 and is coupled to the ground level. In addition, the third N-type doped region 45 is also formed on the P-type substrate 41.

The N-type well 46 is formed between the first N-type doped region 42 and the third N-type doped region 45. Therefore, the N-type well 46 forms the resistance between the first N-type doped region 42 and the third N-type doped region 45. In addition, an isolation element 48 is formed between the second N-type doped region 43 and the third N-type doped region 45. The isolation element 48 is a shallow trench or a field oxide formed by LOCOS.

In addition, the second N-type doped region 43, the P-type substrate 41 and the third N-type doped region 45, form a parasitical bipolar junction transistor Q1, and the first N-type doped region 42, the P-type substrate 41 and the second N-type doped region 43, form another parasitical bipolar junction transistor Q2.

When an ESD event occurs at the pad 30, the ESD current flows through the first N-type doped region 42, the N-type well 46 and the third N-type doped region 45 and causes the junction of the collector and the base of the bipolar junction transistor Q1 voltage breakdown to turn on the bipolar junction transistor Q1. In addition, when the bipolar junction transistor Q1 is turned on, the large current flowing through the N-type well 46 turns on the bipolar junction transistor Q2. According to the ESD protection device of the invention, the N-type well 46 formed between the first N-type doped region 42 and the third N-type doped region 45 increases the resistance between the first N-type doped region 42 and the third N-type doped region 45. Therefore, the holding voltage is increased. In addition, the depth of the bottom of the N-type well 46 is adjusted to obtain the demanded ESD protection effect.

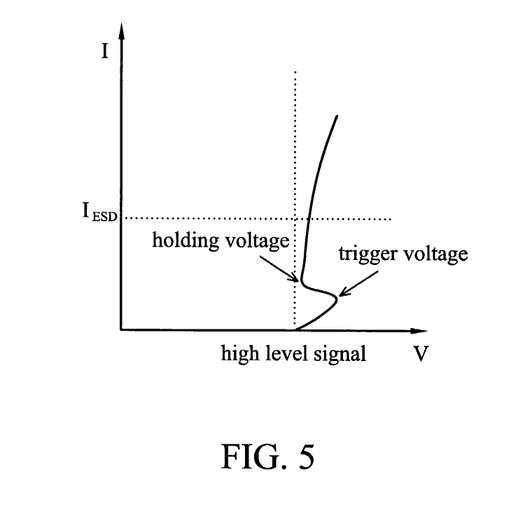

FIG. 5 shows the drain current of the ESD protection device against the input voltage according to the embodiment of the present invention. When the voltage level of the pad 30 is higher than the trigger voltage, the ESD protection device is enabled and immediately goes to snapback mode to prevent ESD damage to the memory device. In FIG. 5, the holding voltage is higher than the high level signal received by the pad 30 when operating in normal mode. Therefore, the drain is independent of the high level signal received by the pad 30 when operating in normal mode.

Moreover, the ESD protection device according to the embodiment of the present invention comprises two discharge paths, the paths through the bipolar junction transistors Q1 and Q2. Therefore, the ESD protection effect is improved even when the holding voltage is increased. In addition, the large N-type well 46 can withstand a large ESD current, thus the ESD protection effect is further improved.

The foregoing description of the preferred embodiments of this invention has been presented for purposes of illustration and description. Obvious modifications or variations are possible in light of the above teaching. The embodiments were chosen and described to provide the best illustration of the principles of this invention and its practical application to thereby enable those skilled in the art to utilize the invention in various embodiments and with various modifications as are suited to the particular use contemplated. All such modifications and variations are within the scope of the present invention as determined by the appended claims when interpreted in accordance with the breadth to which they are fairly, legally, and equitably entitled.

What is claimed is:

1. An ESD protection device set between a memory device, a second voltage level and a pad coupled to a first voltage level, comprising:
a first type substrate;
a first second type doped region formed on the first type substrate and coupled to the first voltage level;
a second second type doped region formed on the first type substrate and coupled to the second voltage level;
a third second type doped region formed on the first type substrate;
a second type well formed between the first second type doped region and the third second type doped region; and
an isolation element formed between the second second type doped region and the third second type doped region.

2. The ESD protection device as claimed in claim 1, wherein the first type substrate is a P-type substrate.

3. The ESD protection device as claimed in claim 2, wherein the first second type doped region, the second second type doped region and the third second type doped region are N-type doped regions.

4. The ESD protection device as claimed in claim 3, wherein the second type well is N-type well.

5. The ESD protection device as claimed in claim 1, wherein the second second type doped region, the first type substrate and the third second type doped region form a first bipolar junction transistor.

6. The ESD protection device as claimed in claim 1, wherein the first second type doped region, the first type substrate and the second second type doped region form a second bipolar junction transistor.

7. The ESD protection device as claimed in claim 1, wherein the isolation element is field oxide.

8. The ESD protection device as claimed in claim 1, wherein the isolation element is a shallow trench.

9. The ESD protection device as claimed in claim 1, wherein the first voltage level is the input voltage of the pad.

10. The ESD protection device as claimed in claim 1, wherein the second voltage level is ground level.

11. An ESD protection device set between a memory device, a second voltage level and a pad coupled to a first voltage level, comprising:
a P-type substrate;
a first N-type doped region formed on the P-type substrate and coupled to the first voltage level;
a second N-type doped region formed on the P-type substrate and coupled to the second voltage level;
a third N-type doped region formed on the P-type substrate;
a N-type well formed between the first N-type doped region and the third N-type doped region; and
an isolation element formed between the second N-type doped region and the third N-type doped region.

12. The ESD protection device as claimed in claim 11, wherein the second N-type doped region, the P-type substrate and the third N-type doped region form a first bipolar junction transistor.

13. The ESD protection device as claimed in claim 11, wherein the first N-type doped region, the P-type substrate and the second N-type doped region form a second bipolar junction transistor.

14. The ESD protection device as claimed in claim 11, wherein the isolation element is field oxide.

15. The ESD protection device as claimed in claim 11, wherein the isolation element is a shallow trench.

16. The ESD protection device as claimed in claim 11, wherein the first voltage level is the input voltage of the pad.

17. The ESD protection device as claimed in claim 11, wherein the second voltage level is ground level.
